(19) United States
(12) Patent Application Publication
(10) Pub. No.: US 2007/0287266 A1
(43) Pub. Date: Dec. 13, 2007

(54) Method of cutting and machining a silicon wafer

(75) Inventors: Chen-Kuei Chung, Tainan (TW); Meng-Yu Wu, Tainan (TW); Yun-Chieh Sung, Tainan (TW)

Correspondence Address: BIRCH STEWART KOLASCH & BIRCH, PO BOX 747, FALLS CHURCH, VA, 22040-0747, US

(73) Assignee: National Cheng Kung University, Tainan (TW)

(21) Appl. No.: 11/653,292

(22) Filed: Jan. 16, 2007

(30) Foreign Application Priority Data
Jun. 13, 2006 (TW) 095121048

(51) Int. Cl. H01L 21/00

(52) U.S. Cl. 438/460

(57) ABSTRACT

The present invention discloses a method of cutting and machining a silicon wafer. It comprises to provide a CO₂ laser apparatus, a glass or a metal-coated substrate to be put on a supporter and a silicon wafer to be fixed on the glass or the metal-coated substrate. The CO₂ laser source is to be focused on the silicon wafer for cutting and profile machining. The invention can provide a low cost, high yield, high throughput, and high precision for cutting and machining a silicon wafer.

### BACKGROUND OF THE INVENTION

1. Field of the Invention

This invention relates to a method of cutting and machining a silicon wafer, particularly to a silicon wafer cutting and machining method using CO₂ laser.

2. Description of the Related Art

With the development of the high tech industry, the application of hard-brittle materials becomes wider, especially in the field of photonics, semiconductors, informatics and electronics. The silicon wafer is an often used material for electronic components but its high hardness and high brittleness cause some difficulties in the cutting and machining. Therefore, the research in the machining technology for cutting silicon wafers becomes an indispensable issue at present.

In the traditional methods of cutting and machining a silicon wafer, we can distinguish, by the difference in the processing mechanisms, mainly two machining methods: contact method and non-contact method. The contact machining uses a diamond cutter to cut the silicon wafer. Since the silicon wafer is a hard and brittle material, all the cutting conditions, such as the force exerted, the cutting speed, the cutting depth and the cutting angles, have to be controlled probably to prevent any fracture or crack on the surface of the silicon wafer. FIG. 1 is a schematic diagram of cutting a silicon wafer using a diamond cutter wherein the line of dashes shows the planned cutting path, the arrow indicates the direction of exerted force and the straight line demonstrates the real cutting result. While cutting the silicon wafer, the imprecision of the force exerting direction can easily caused a shifting in the cutting direction (as shown in FIG. 1b) and the uneven exerting force and cutting speed can easily causes some irregular cracks (as shown in FIG. 1c). The above-mentioned shortcomings can be overcome by double cutting method where a two-step cutting (stepping cutting) method is applied and a shallow cutting is processed before a penetrating cutting to diminish the cracks, however, there are still many shortcomings in stepping cutting. For example, the one-step cutting is replaced by the two-step cutting thus reduces evidently the machining capacity. Furthermore, the inclining cutter used in the first step cutting is expensive and need to be treated and replaced regularly, which increases the cost of cutting and machining. Besides, contact method of cutting and machining for silicon wafer is slow in cutting speed, easy to hurt hand, low in machining precision and can only process linear cut due to the design of cutting devise. When it comes to cutting of special shapes, such as a round or a half moon, the possibility of fractures or cracks on the silicon wafer increases considerably. Moreover, the dusts and fragments produced during the contact cutting and machining will pollute the components. Consequently, the contacting cutting method cannot satisfy the industrial need in the aspect of machining precision and fineness.

As for the non-contact machining method for cutting silicon wafers, high-energy laser with short wavelength is used. Laser beams focus on the surface of the target object in a very short time and release energy simultaneously. The bonds of the material are broken by the photochemical action and the photoetching or cutting can be achieved by moving the scanning laser beam or the working platform to produce the desired shape. Conventional laser photoetching technology uses short-wave ultraviolet laser, near infrared wavelength laser (such as Nd:YAG laser) or excimer laser to machine silicon wafers. As in U.S. Pat. No. 6,562,698, two laser beams with different wavelength are used in silicon wafer cutting for improving the low yield in the single contact cutting and low productivity in the stepping cutting.

Non-contact cutting has the advantage of high yield and high productivity without component pollution, and the laser beam can be used to cut all forms of patterns and shapes, including complex curves, which allows it more flexibility and diversity than contact cutting and machining. Therefore, in the semiconductor industry, where the demand of machining precision and fineness is high, the non-contact method is widely used to cut silicon wafers.

Generally speaking, the shorter the wavelength of the laser, the higher the cost and the lower the maximum power is. Therefore, from the view of cost/laser-power, the best is to provide the longest wavelength need for the desired result. However, the laser beams used nowadays are mainly short-wave ultraviolet laser or near infrared wavelength laser, such as Excimer or Nd:YAG laser, which is of high machining cost. The low cost far infrared laser CO₂ cannot be used on machining and/or cutting of a silicon wafer because it cannot normally be absorbed by the silicon. Please see attachment I, it shows the result of 100 times photoetching on the surface of a silicon wafer using CO₂ laser of 10.6 μm wavelength, 30 W power and 5.715 mm/sec scanning speed. As the result shows, the CO₂ laser beam passes directly through the silicon wafer without being absorbed, thus cannot be used on the cutting and/or machining of silicon wafers.

For these reasons, a high yield, high productivity and low cost cutting technology is necessary for overcoming the above-mentioned shortcomings.

### SUMMARY OF THE INVENTION

The main purpose of the present invention is to provide a cutting and machining method of silicon wafers which keeps the high yield and high productivity advantage of non-contact cutting technology and reduces the cost of silicon wafer cutting and machining.

The secondary purpose of the invention is to provide a cutting and machining method which can perform linear or special shape cutting on the silicon wafer according to the mechanical and functional need of the microelectronic or photoelectronic components.

To accomplish the above-mentioned purposes, the cutting and machining method for silicon wafers disclosed in the invention contains the following steps: a laser apparatus which includes a CO₂ laser source and a glass or a metal-coated supporting substrate which is put on a supporter are provided, and the CO₂ laser is focused on the silicon wafer for linear or special shape machining.

The method of cutting and machining a silicon wafer disclosed in the invention uses a fixture to fasten the silicon wafer and the supporting substrate, a glue layer that allows the penetration of CO₂ laser can also be applied between the supporting substrate and the silicon wafer for a close contact.

In the method of cutting a silicon wafer disclosed in the invention, the CO₂ laser can be focused on the surface or inside of the silicon wafer for linear or irregular shape cutting and machining.

Besides, the invention discloses an apparatus for the silicon wafer cutting and machining which comprises a glass or metal-coated supporting substrate with predetermined thickness for supporting a silicon wafer, a laser source used to produce a CO₂ laser whose focus is above the substrate and whose distance with the supporting substrate is smaller or equal to the thickness of the silicon wafer.

According the method of cutting a silicon wafer in the invention, the silicon wafer cutting and machining using CO₂ laser can cut and machine the silicon wafer effectively and rapidly, the linear or special shape cutting and machining can be operated safely and rapidly, and the maintenance of the equipment is simple. The advantage of high yield, high precision and low cost can thus be achieved.

The purposes, characteristics and advantages mentioned in foregoing summary and the following detailed description of the preferred embodiments of the present invention will be best understood when read in conjunction with the appended drawings in the following section.

### BRIEF DESCRIPTION OF THE DRAWINGS

These and other features, aspects, and advantages of the present invention will be more fully understood by reading the following detailed description of the preferred embodiment, with reference made to the accompanying drawings as follows:

FIG. 1 is a schematic diagram showing a diamond cutter cutting a silicon wafer;

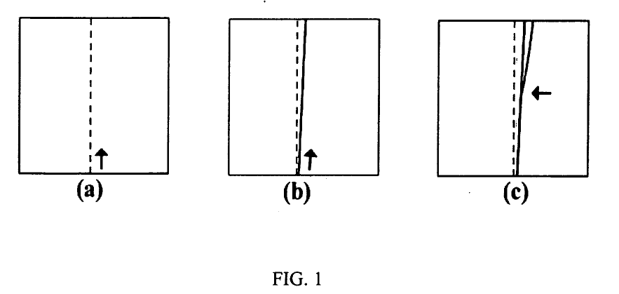

FIG. 2 is the process-flow diagram of CO₂ laser applied for cutting and machining a silicon wafer in the invention;

FIG. 3 is a schematic diagram of the procedure of cutting a silicon wafer using the method in the disclosed invention; and

FIG. 4 is a schematic diagram showing the experimental setup used for cutting and machining a silicon wafer in the invention.

### DETAILED DESCRIPTION OF THE PREFERRED EMBODIMENT

The present invention will be described in terms of specific embodiments incorporating details to facilitate the understanding of the principles of construction and operation of the invention. As such, references herein to specific embodiments and details thereof are not intended to limit the scope of the claims appended hereto.

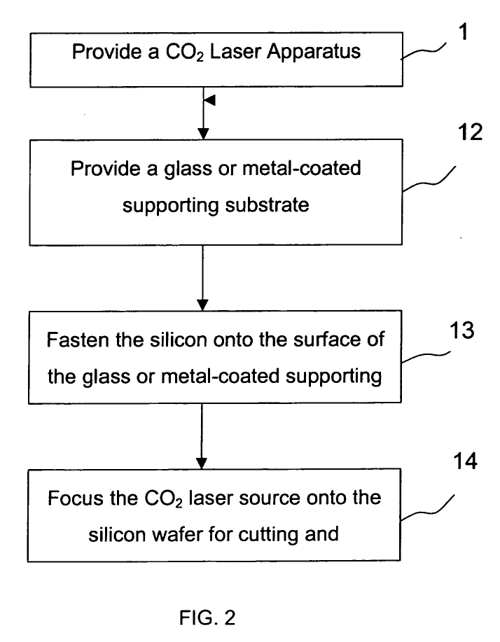

In FIG. 2, the schematic diagram sketch shows the process flow of cutting and machining a silicon wafer using a CO₂ laser. The method of cutting and machining a silicon wafer in the invention includes the following steps:

Step 11: a laser apparatus (2) is provided with a CO₂ laser source (21).

Step 12: a supporting substrate (25) is placed on a supporter (26), wherein the supporting substrate (25) is a glass or metal-coated substrate.

The metal-coated substrate (25) is made of materials with low thermal conductivity coefficient. The substrate can be made of glass, oxidizing metal or ceramics and the metal coating can be made of any mixture of aluminum, titanium, chromium, tantalum, nickel, iron, cobalt, vanadium, tungsten, zirconium, zinc, copper, silver and gold. The thickness of the metal coat is between 10-1000 nm. In a better case, if the metal coat is made of aluminum, titanium, chromium, tantalum, nickel, iron, cobalt, vanadium, tungsten, zirconium and zinc, the thickness of the metal coat is between 30-80 nm.

Step 13: a silicon wafer (24) is put on the surface of supporting substrate (26).

A fixture (not shown in the figure) can be used as an approach to fasten the silicon wafer (24) on the supporting substrate (25); a glue layer which allows the penetration of CO₂ laser between the silicon wafer (24) and the substrate (25) can be used as another approach to fix the silicon wafer (24) closely to the supporting substrate (25). In the better embodiment, a fixture is used to fasten and close contact the silicon wafer (24) and the supporting substrate (25) for best result of cutting and machining.

Step 14: A CO₂ laser is used to cut the silicon wafer (24).

The height of focus of the CO₂ laser is adjusted to let the CO₂ laser source (21) be focused on the silicon wafer (24) for cutting and machining. In which, the focus point of the CO₂ laser source (21) can be on the surface or at inner part of the silicon wafer (24). The focus point of the CO₂ laser source (21) can be adjusted by a set of reflector (22) and focusing lens (23) situated between the CO₂ laser source (21) and the supporting substrate (25); the focus point can also be adjusted by fine-tuning the vertical direction of the supporter (26). The two focus-adjusting approaches can be combined for use. By modifying the laser processing parameters, such as the power of laser source, the scanning speed and cutting passes, adjusting the laser source focus or moving the working platform, the desired linear or irregular shape cutting and machining can be achieved.

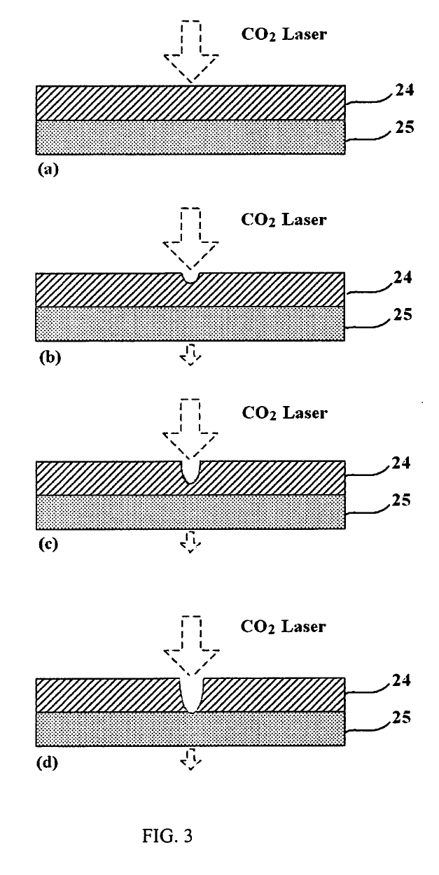

The better method of cutting and machining a silicon wafer disclosed by the invention is to put the silicon wafer (24) on the supporting substrate (25) and then use a fixture to fasten the silicon wafer (24) on the supporting substrate (25) for a close contact between the two objects. When the CO₂ laser beam focuses on the silicon wafer (24), the glass or metal-coated substrate (25) placed under the silicon wafer (24) can lower the heat diffusion and avoid the lost of heat. The heat of the CO₂ laser beam can thus focus on the silicon wafer (24) for cutting and machining. FIG. 3 is a schematic diagram of cutting silicon wafer using the method disclosed by the invention: (a) is before etching; (b) is the initial stage of photoetching where low-pass laser beam scanning to etch the silicon wafer (24) with the help of the supporting substrate (25) to heat the silicon wafer for preserving high temperature on the surface of the silicon wafer (24) and the supporting substrate (25), and the CO₂ laser beam has been absorbed to etch the silicon wafer (24) with shallow depth; (c) is the medium stage of CO₂ laser etching where the laser beam cause deeper etching effect on the silicon wafer (24); (d) the later stage of CO₂ laser etching where the laser etching has already penetrate the whole silicon wafer (24). As we can observe from the figure, the etching starts from the top surface of the silicon wafer (24) and processes toward the interface between the silicon wafer (24) and the supporting substrate (25) implies that the silicon wafer (24) must absorb the energy of CO₂ laser with the assistance of the glass or metal-coated substrate (25) to modify the silicon wafer (24) absorption through some mechanism involved in the photo-material interaction at high temperature.

In one embodiment of the invention, the result of the method of the invention using a CO₂ laser with the 10.6 μm wavelength, 30 W power and 5.715 mm/sec scanning speed under normal atmosphere without any help from extra gas or liquid and photoetching 20 times linearly on the silicon wafer (24) (see attachment II). As we can see from the attachment, photoetching the silicon wafer (24) using the method of the invention can produce a smooth cut surface of the silicon wafer (24), a high cutting precision without any irregular cracks or bits.

In another embodiment of special shape cutting and machining. the method of cutting a silicon wafer using CO₂ laser disclosed by the invention can successfully be used for cutting the silicon wafer (24) in irregular shapes (see the attachment III, (a) is a composite diagram after a heart-shape machining of the silicon wafer (24) and (b) is a separated diagram after a heart-shape machining of the silicon wafer (24)). The limitation that contact cutting of a diamond cutter can only process linear cutting can thus be overcome.

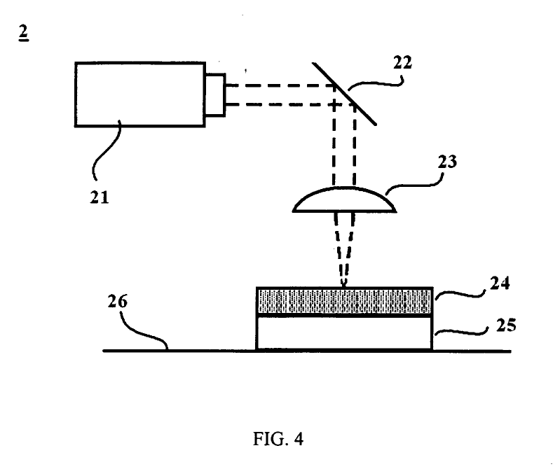

FIG. 4 is a schematic experimental setup of the laser apparatus used for cutting and machining a silicon wafer in the present invention. The laser apparatus (2) comprises a supporting substrate (25) which is a glass substrate with certain thickness and is used for bearing a silicon wafer (24), a laser source (21) used to produce a CO₂ laser beam wherein its focus point is above the substrate (25) and its distance with the supporting substrate (25) is smaller or equal to the thickness of silicon wafer (24). The glass substrate can be replaced by a metal-coated substrate wherein the metal-coated side of the substrate should be adjacent to the silicon wafer.

The laser apparatus (2) contains a reflector (22) and a focusing lens (23) set between the CO₂ laser source (21) and the supporting substrate (25) for adjusting the focus point of the CO₂ laser source (21). Moreover, the laser apparatus (2) can contain a supporter (26) to eventually adjust the focus point of the CO₂ laser source (21). The laser apparatus (2) of the invention can furthermore contains a fixture (not shown in the figures) to fasten the silicon wafer (24) on to the supporting substrate (25) for a close contact between the two objects.

The method of cutting and machining a silicon wafer of the invention uses CO₂ laser for cutting and machining the silicon wafer. Not only the shortcoming of contact cutting, such as low productivity, low yield, low safety, high abrasion of cutters and inability of machining special shapes can be overcome; but the weakness of high cost and complex maintenance of the equipment of non-contact cutting can also be improved. Using the method of the invention for cutting and machining a silicon wafer can rapidly and effectively cut a silicon wafer and provide a high productivity, high yield, high precision and high safety technology. As the maintenance of the equipment is simple, the machining cost can largely be reduced. The method is suitable for the semiconductor industry which has high demand on cutting large-size silicon wafers.

The present invention has been described in terms of specific embodiments incorporating details to facilitate the understanding of the principles of construction and operation of the invention. As such, references herein to specific embodiments and details thereof are not intended to limit the scope of the claims appended hereto. It will be apparent to those skilled in the art that modifications ca be made to the embodiments chosen for illustration without departing from the spirit and scope of the invention. The scope of patent protection of the present invention should be referred to the claims appended hereto.

What we claim is:

1. A method of cutting and machining a silicon wafer which contains the following steps:
a. providing a laser apparatus equipped with a CO₂ laser source;
b. providing a glass substrate to be put on a supporter;
c. putting a silicon wafer on to the glass substrate; and
d. focusing the CO₂ laser source onto the silicon wafer for cutting and machining.

2. The method of cutting and machining a silicon wafer of claim 1, wherein the step c further comprises:
providing a fixture to fasten the silicon wafer and the glass substrate for a close contact.

3. The method of cutting and machining a silicon wafer of claim 1, wherein there is a glue layer on the surface of the glass substrate for a tight grouping with the silicon wafer.

4. The method of cutting and machining a silicon wafer of claim 3, wherein the glue layer consists of a glue material that CO₂ laser can penetrate.

5. The method of cutting and machining a silicon wafer of claim 1, wherein the focus point of the CO₂ laser source is on the surface of the silicon wafer.

6. The method of cutting and machining a silicon wafer of claim 1, wherein the focus point of the CO₂ laser source is at inner part of the silicon wafer.

7. The method of cutting and machining a silicon wafer of claim 1, wherein the CO₂ laser source can process linear and irregular shape of cutting and machining on the silicon wafer.

8. The method of cutting and machining a silicon wafer of claim 1, wherein the laser apparatus comprises a focusing lens between the CO₂ laser source and the supporting substrate for adjusting the focus point of the CO₂ laser source.

9. A method of cutting and machining a silicon wafer which contains the following steps:
a. providing a laser apparatus equipped with a CO₂ laser source;
b. providing a metal-coated substrate to be put on a supporter;
c. putting a silicon wafer on to the metal-coated substrate; and
d. focusing the CO₂ laser source onto the silicon wafer for cutting and machining.

10. The method of cutting and machining a silicon wafer of claim 9, wherein the metal coat can be made of any mixture of aluminum, titanium, chromium, tantalum, nickel, iron, cobalt, vanadium, tungsten, zirconium, zinc, copper, silver and gold.

11. The method of cutting and machining a silicon wafer of claim 9, wherein the metal coat is made of aluminum, titanium, chromium, tantalum, nickel, iron, cobalt, vanadium, tungsten, zirconium or zinc.

12. The method of cutting and machining a silicon wafer of claim 9, wherein the thickness of the metal coat is between 10-1000 nm.

13. The method of cutting and machining a silicon wafer of claim 9, wherein the thickness of the metal coat is between 30-80 nm.

14. The method of cutting and machining a silicon wafer of claim 9, wherein the substrate is made of a material with low heat diffusion coefficient.

15. The method of cutting and machining a silicon wafer of claim 9, wherein the substrate is made of glass, oxidizing metal or ceramics.

16. The method of cutting and machining a silicon wafer of claim 9, wherein the step c further comprises:
providing a fixture to fasten the silicon wafer and the metal-coated substrate for a tight combination.

17. The method of cutting and machining a silicon wafer of claim 9, wherein the focus point of the CO₂ laser source is on the surface of the silicon wafer.

18. The method of cutting and machining a silicon wafer of claim 9, wherein the focus point of the CO₂ laser source is at inner part of the silicon wafer.

19. The method of cutting and machining a silicon wafer of claim 9, wherein the CO₂ laser source can process linear and irregular shape of cutting and machining on the silicon wafer.

20. The method of cutting and machining a silicon wafer of claim 9, wherein the laser apparatus comprises a focusing lens between the CO₂ laser source and the supporting substrate for adjusting the focus point of the CO₂ laser source.

21. A device used for cutting and machining a silicon wafer which comprises:
a glass substrate with a certain thickness for supporting a silicon; and
a laser source for emitting a CO₂ laser;
wherein the focus point of the laser source is above the substrate and whose distance with the supporting substrate is smaller or equal to the thickness of the silicon wafer.

22. The device used for cutting and machining a silicon wafer of claim 21, wherein the glass substrate can be replaced by a metal-coated substrate and the metal-coated side of the substrate should be adjacent to the silicon wafer.

23. The device used for cutting and machining a silicon wafer of claim 22, wherein the metal coat is made of any mixture of aluminum, titanium, chromium, tantalum, nickel, iron, cobalt, vanadium, tungsten, zirconium, zinc, copper, silver and gold.

24. The device used for cutting and machining a silicon wafer of claim 21, wherein the device contains furthermore a fixture to fasten the silicon wafer and the metal-coated substrate for a tight combination.

25. The device used for cutting and machining a silicon wafer of claim 21, wherein the device contains additionally a focusing lens between the CO₂ laser source and the supporting substrate for adjusting the focus point of the CO₂ laser source
